(19) United States
(12) Patent Application Publication
(10) Pub. No.: US 2012/0244678 A1
(43) Pub. Date: Sep. 27, 2012

(54) SEMICONDUCTOR DEVICE WAFER BONDING METHOD

(75) Inventor: Takashi Mori, Ota-Ku (JP)

(73) Assignee: DISCO CORPORATION, Tokyo (JP)

(21) Appl. No.: 13/423,477

(22) Filed: Mar. 19, 2012

(30) Foreign Application Priority Data
Mar. 25, 2011 (JP) 2011-067623

(51) Int. Cl. H01L 21/762

(52) U.S. Cl. 438/455; 257/E21.567

(57) ABSTRACT

A semiconductor device wafer bonding method bonds a first semiconductor device wafer having a plurality of semiconductor devices with a plurality of projecting electrodes to a second semiconductor device wafer having a plurality of electrodes respectively corresponding to the projecting electrodes of the first semiconductor device wafer. An insulator is applied and fills the spacing between adjacent projecting electrodes. The first semiconductor device wafer is planarized to expose the end surfaces of the projecting electrodes, and the first semiconductor device wafer is bonded to the second semiconductor device wafer with an anisotropic conductor interposed between the projecting electrodes of the first semiconductor device wafer and the electrodes of the second semiconductor device wafer, to thereby respectively connect the electrodes through the anisotropic conductor.

### BACKGROUND OF THE INVENTION

1. Field of the Invention

The present invention relates to a semiconductor device wafer bonding method of bonding a plurality of semiconductor device wafers to each other.

2. Description of the Related Art

In a semiconductor device fabrication process, a plurality of crossing division lines called streets are formed on the front side of a semiconductor device wafer to partition a plurality of regions where a plurality of semiconductor devices such as ICs and LSIs are respectively formed. The semiconductor device wafer is divided along the division lines to obtain the individual semiconductor devices as semiconductor device chips. These semiconductor devices are widely used in various electrical equipment.

For the purpose of reducing the size and thickness of electrical equipment, a stacked semiconductor device configured by stacking a plurality of semiconductor devices has recently been put into practical use. Such a stacked semiconductor device is manufactured by stacking a plurality of semiconductor device wafers to form a stacked wafer and next cutting this stacked wafer along the division lines by using a cutting apparatus to thereby divide the stacked wafer into individual semiconductor device chips.

As a technique for realizing the miniaturization of a semiconductor device chip, there has been put into practical use a mounting technique called flip chip bonding such that a plurality of projecting electrodes called bumps are formed on the device surface of the chip and these bumps are respectively directly bonded to electrodes formed on a wiring board (see Japanese Patent Laid-open No. 2001-237278, for example).

In bonding a first semiconductor device wafer having a plurality of semiconductor devices with bumps to a second semiconductor device wafer to form a stacked wafer, an anisotropic conductive material (anisotropic conductor) such as an anisotropic conductive film (ACF) or an anisotropic conductive paste (ACP) is used. The anisotropic conductive film is obtained by dispersing conductive metal particles in a thermosetting epoxy resin and forming the resin into a film. Each conductive metal particle is a spherical member formed of nickel, gold, etc. and has a diameter of several micrometers. Each conductive metal particle has a multilayer structure mainly composed of a nickel layer as an inner layer, a gold plating layer formed on the nickel layer, and an insulating layer as an outermost layer. On the other hand, the anisotropic conductive paste is obtained by forming the above resin containing the conductive metal particles into a paste.

For example, after mounting a first semiconductor device wafer having bumps through an anisotropic conductive material on a second semiconductor device wafer having electrodes, heat and pressure are applied to the first semiconductor device wafer by using a pad or the like. As a result, the conductive metal particles dispersed in the anisotropic conductive material present between the bumps of the first semiconductor device wafer and the electrodes of the second semiconductor device wafer are brought into pressure contact with each other to thereby form a conducting path between the bumps and the electrodes. As described above, each conductive metal particle has an insulating layer as an outermost layer, so that the conductive metal particles present between the bumps and not pressurized still retain the insulating layer, thereby maintaining the insulation between the bumps. Thus, anisotropy is exhibited so that conductivity is maintained in a direction perpendicular to the device surface of the chip and insulation is maintained in a direction parallel to the device surface of the chip. Accordingly, even when the spacing between the bumps is small, the first semiconductor device wafer can be bonded to the second semiconductor device wafer without a short circuit between the bumps.

### SUMMARY OF THE INVENTION

With a reduction in size and thickness and an advance in functionality of recent electronic equipment, the pitch of the bumps on the semiconductor device chip is reduced. Accordingly, there is a possibility that a conducting path may be formed between the bumps at the time of filling the spacing between the bumps with the anisotropic conductive material.

It is therefore an object of the present invention to provide a semiconductor device wafer bonding method using an anisotropic conductive material which can eliminate the possibility of formation of a conducting path between the bumps.

In accordance with an aspect of the present invention, there is provided a semiconductor device wafer bonding method of bonding a first semiconductor device wafer having a plurality of semiconductor devices with a plurality of projecting electrodes to a second semiconductor device wafer having a plurality of electrodes respectively corresponding to the projecting electrodes of the first semiconductor device wafer, the semiconductor device wafer bonding method including an insulator applying step of applying an insulator to the front side of the first semiconductor device wafer where the projecting electrodes are formed to fill the spacing between any adjacent ones of the projecting electrodes with the insulator; a projecting electrode end exposing step of planarizing the front side of the first semiconductor device wafer covered with the insulator to expose the end surfaces of the projecting electrodes after performing the insulator applying step; and a bonding step of bonding the first semiconductor device wafer to the second semiconductor device wafer with an anisotropic conductor interposed between the projecting electrodes of the first semiconductor device wafer and the electrodes of the second semiconductor device wafer respectively corresponding to the projecting electrodes to thereby respectively connect the projecting electrodes and the electrodes through the anisotropic conductor after performing the projecting electrode end exposing step.

According to the semiconductor device wafer bonding method of the present invention, the spacing between the adjacent projecting electrodes is filled with the insulator, and the first semiconductor device wafer is next bonded through the anisotropic conductor to the second semiconductor device wafer. Accordingly, no conducting path is formed between the adjacent projecting electrodes. Further, the spacing between the adjacent projecting electrodes is filled with the insulator, and the insulator covering all of the projecting electrodes is planarized to uniform the heights of the projecting electrodes. Accordingly, faulty connection due to variations in height between the projecting electrodes can be prevented.

In the projecting electrode end exposing step, the insulator is planarized to expose the end surfaces of the projecting electrodes, so that an oxide film having a thickness of several angstroms is undesirably formed on the end surfaces of the projecting electrodes exposed to the atmosphere. To remove the oxide film, any processing such as dry etching or wet etching must be performed. However, there is a problem that it is very difficult to etch only the end surfaces of the projecting electrodes. In this respect, the first semiconductor device wafer is bonded through the anisotropic conductor to the second semiconductor device wafer according to the present invention. Accordingly, in bonding the first and second semiconductor device wafers, the conductive metal particles in the anisotropic conductor can penetrate the oxide film to form a conducting path, thereby eliminating the need for removal of the oxide film.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a flowchart showing a semiconductor device wafer bonding method according to an embodiment of the present invention;

FIG. 2 is a perspective view of a semiconductor device wafer having a plurality of semiconductor devices with bumps;

FIG. 3 is a schematic side view of the semiconductor device wafer;

FIG. 4 is a partially sectional side view showing an insulator applying step;

FIG. 5 is a partially sectional side view showing a projecting electrode end exposing step;

FIG. 6 is a partially sectional side view of the semiconductor device wafer in the condition after performing the projecting electrode end exposing step;

FIG. 7 is a partially sectional side view showing a bonding step; and

FIG. 8 is a partially sectional side view showing a dividing step.

### DETAILED DESCRIPTION OF THE PREFERRED EMBODIMENT

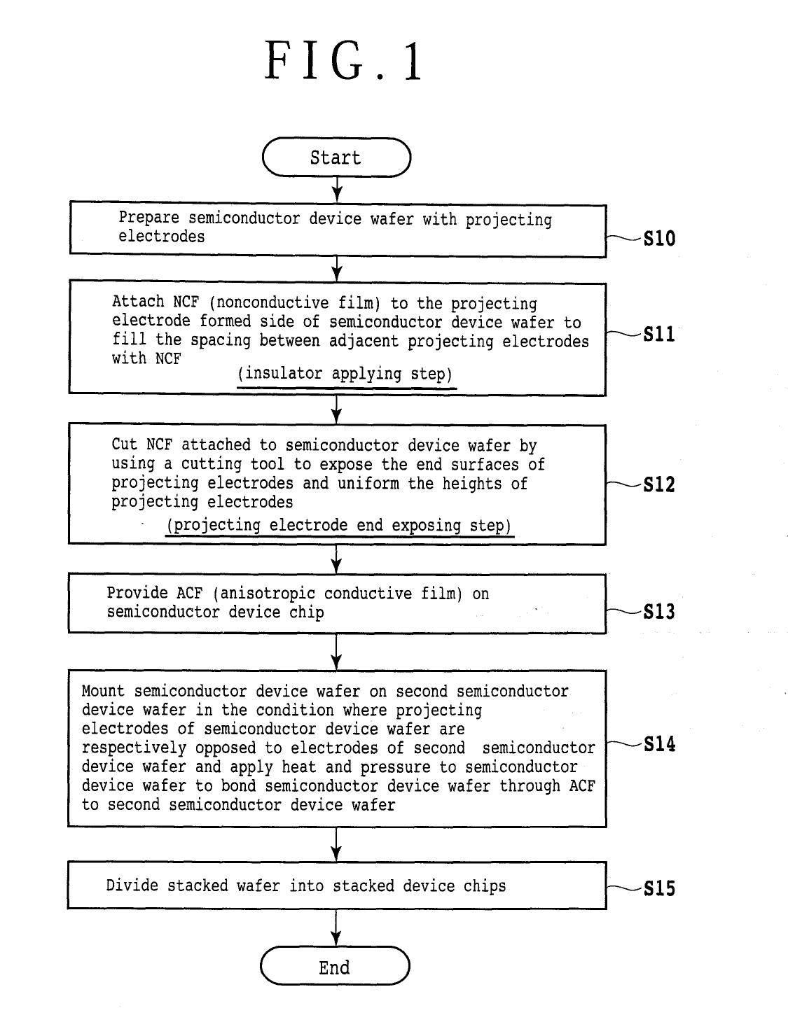

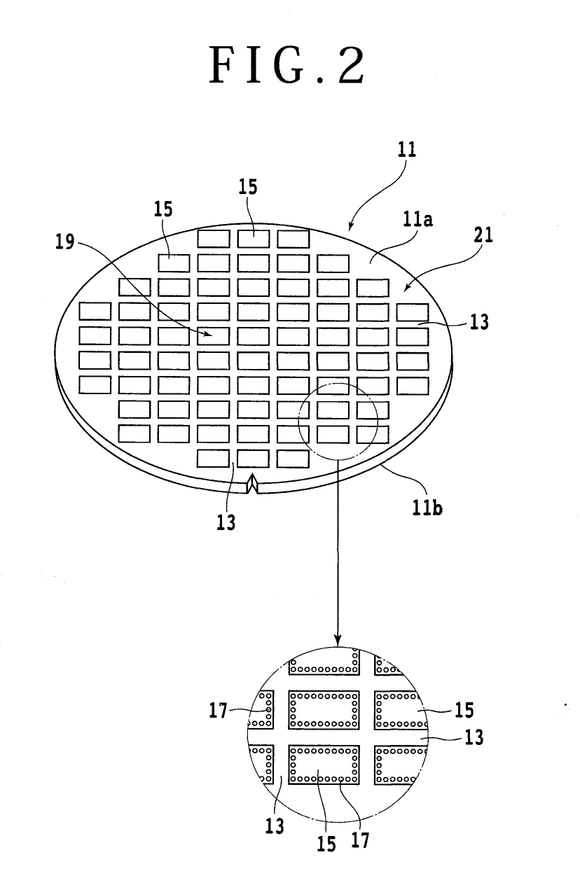

An embodiment of the present invention will now be described in detail with reference to the drawings. In a semiconductor device wafer bonding method according to the embodiment of the present invention, a preparing step as a step S10 of a flowchart shown in FIG. 1 is first performed to prepare a semiconductor device wafer 11 with projecting electrodes (bumps). As shown in FIG. 2, the semiconductor device wafer 11 has a front side 11a and a back side 11b. A plurality of orthogonally crossing division lines (streets) 13 are formed on the front side 11a to thereby partition a plurality of rectangular regions where a plurality of semiconductor devices 15 are respectively formed.

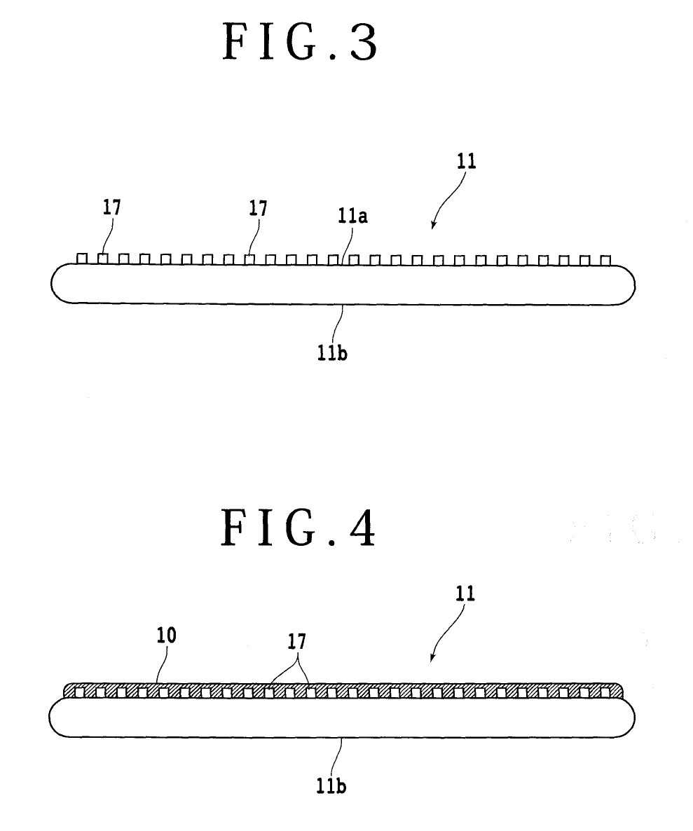

As shown in an enlarged view of FIG. 2, a plurality of projecting bumps 17 are formed on each semiconductor device 15 along the four sides thereof. Since the bumps 17 are formed along the four sides of each semiconductor device 15, the semiconductor device wafer 11 has a bump formed area 19 where the bumps 17 are formed and a bump unformed periphery area 21 surrounding the bump formed area 19. FIG. 3 shows a schematic side view of the semiconductor device wafer 11.

After performing the preparing step mentioned above, an insulator applying step as a step S11 shown in FIG. 1 is performed. That is, in the insulator applying step, a nonconductive film (NCF) 10 is attached to the front side (projecting electrode formed side) 11a where the bumps 17) of the semiconductor device wafer 11 are formed as shown in FIG. 4 to fill the spacing between any adjacent ones of the bumps 17 with the nonconductive film 10. The NCF 10 is formed of epoxy resin, for example. The NCF 10 may be replaced by a nonconductive paste (NCP).

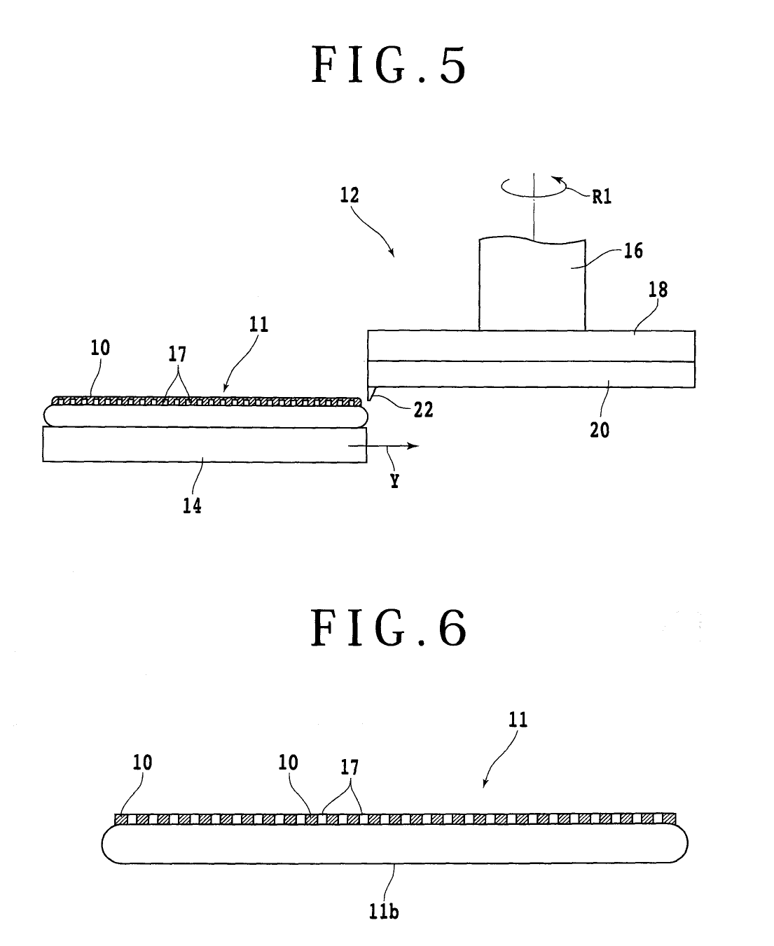

After performing the insulator applying step, a projecting electrode end exposing step as a step S12 shown in FIG. 1 is performed. That is, in this projecting electrode end exposing step, the NCF 10 attached to the semiconductor device wafer 11 is cut by a cutting tool to expose the end surfaces of the bumps 17 and uniform the heights of the bumps 17. Referring to FIG. 5, there is shown a partially sectional side view in the condition where the projecting electrode end exposing step is being performed by using a single point tool cutting apparatus 12. The single point tool cutting apparatus 12 includes a chuck table 14 for holding the semiconductor device wafer 11 covered with the NCF 10 by suction. The single point tool cutting apparatus 12 further includes a spindle 16, a mounter 18 fixed to the lower end of the spindle 16, and a cutting wheel 20 detachably fixed to the lower surface of the mounter 18. The cutting wheel 20 has a single point tool 22 on the lower side.

When the cutting wheel 20 is rotated in the direction shown by an arrow R1 in FIG. 5 and the chuck table 14 is fed at a low speed in the direction shown by an arrow Y in FIG. 5, the nonconductive film (NCF) 10 is cut to be planarized and the end surfaces of the bumps 17 are exposed. FIG. 6 shows a partially sectional side view in the condition after performing the projecting electrode end exposing step. As apparent from FIG. 6, the end surfaces of the bumps 17 are exposed and the spacing between any adjacent ones of the bumps 17 is filled with the NCF 10.

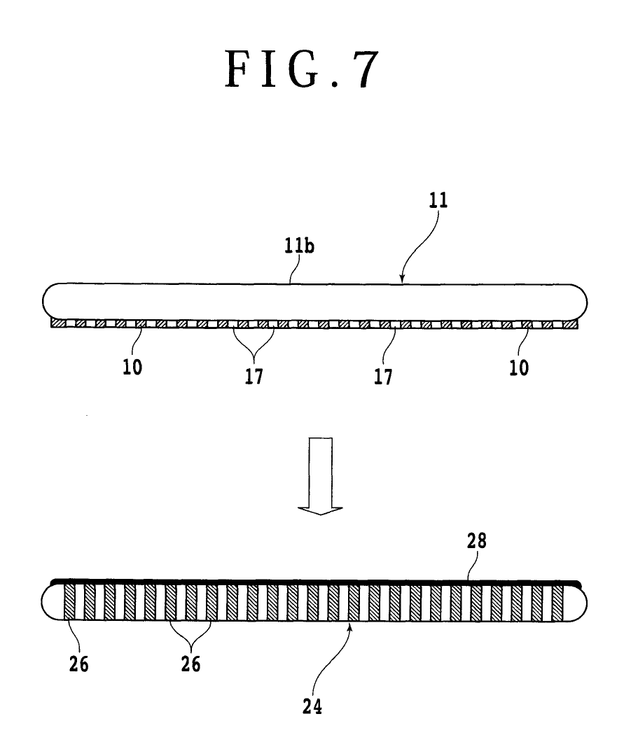

After performing the projecting electrode end exposing step, a step S13 shown in FIG. 1 is performed to provide an anisotropic conductive film (ACF) 28 on the front side 11a of the semiconductor device wafer 11. Alternatively, the ACF 28 may be provided on a second semiconductor device wafer 24 as shown in FIG. 7. The second semiconductor device wafer 24 has a plurality of through electrodes 26 respectively corresponding to the bumps 17 of the semiconductor device wafer 11. The ACF 28 may be replaced by an anisotropic conductive paste (ACP).

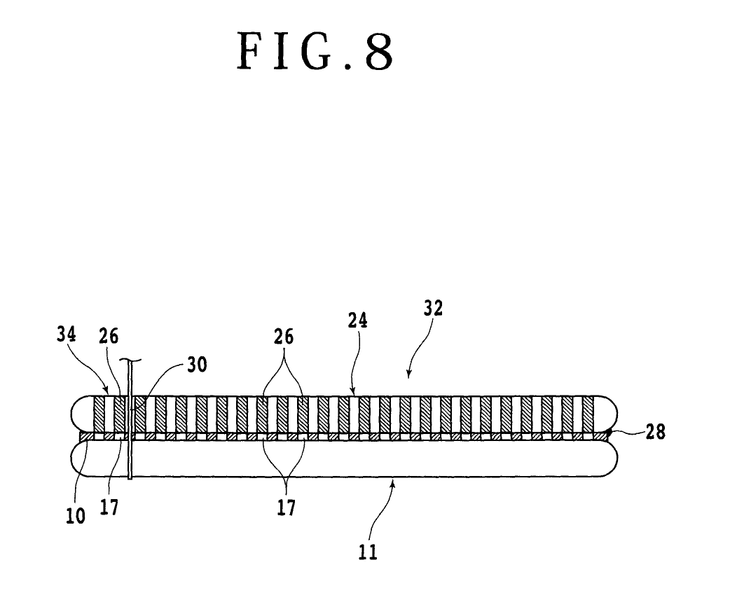

Thereafter, a step S14 shown in FIG. 1 is performed as a bonding step to mount the semiconductor device wafer 11 on the second semiconductor device wafer 24 in the condition where the bumps (projecting electrodes) 17 of the semiconductor device wafer 11 are respectively opposed to the through electrodes 26 of the second semiconductor device wafer 24. Thereafter, pressure is applied to the semiconductor device wafer 11 by using an elastic pad such as a rubber member while heating by a heater or the like. As a result, the conductive metal particles dispersed in the ACF 28 present between the bumps 17 and the through electrodes 26 come into contact with each other and pile to form a conducting path for connecting the bumps 17 of the semiconductor device wafer 11 and the through electrodes 26 of the second semiconductor device wafer 24. The nonconductive film (NCF) 10 is present between any adjacent ones of the bumps 17. Accordingly, although the spacing between the adjacent bumps 17 is small, no short circuit occurs in applying heat and pressure to the semiconductor device wafer 11, so that the semiconductor device wafer 11 can be bonded to the second semiconductor device wafer 24, thereby forming a stacked wafer 32 shown in FIG. 8.

Thereafter, a step S15 shown in FIG. 1 is performed to hold the stacked wafer 32 on a chuck table of a cutting apparatus (not shown) by suction and cut the stacked wafer 32 along the division lines 13 by using a cutting blade 30, thereby dividing the stacked wafer 32 into a plurality of stacked device chips 34 as shown in FIG. 8.

Before performing the bonding step of the step S14, the back side 11b of the semiconductor device wafer 11 may be ground to reduce the thickness of the semiconductor device wafer 11, and the second semiconductor device wafer 24 may also be ground to reduce the thickness thereof. Alternatively, after performing the bonding step of the step S14, the opposite sides of the stacked wafer 32 obtained by bonding the semiconductor device wafer 11 and the second semiconductor device wafer 24 may be ground to reduce the thickness of the stacked wafer 32.

While the plural through electrodes 26 are formed in the second semiconductor device wafer 24 in above-described embodiment, the electrodes of the second semiconductor device wafer 24 are not limited to the through electrodes 26. Any electrodes may be formed on the second semiconductor device wafer 24 so as to respectively correspond to the bumps 17 of the semiconductor device wafer 11.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A semiconductor device wafer bonding method of bonding a first semiconductor device wafer having a plurality of semiconductor devices with a plurality of projecting electrodes to a second semiconductor device wafer having a plurality of electrodes respectively corresponding to said projecting electrodes of said first semiconductor device wafer, said semiconductor device wafer bonding method comprising:
an insulator applying step of applying an insulator to a front side of said first semiconductor device wafer where said projecting electrodes are formed to fill a spacing between any adjacent ones of said projecting electrodes with said insulator;
a projecting electrode end exposing step of planarizing the front side of said first semiconductor device wafer covered with said insulator to expose end surfaces of said projecting electrodes after performing said insulator applying step; and
a bonding step of bonding said first semiconductor device wafer to said second semiconductor device wafer with an anisotropic conductor interposed between said projecting electrodes of said first semiconductor device wafer and said electrodes of said second semiconductor device wafer to thereby respectively connect said projecting electrodes and said electrodes after performing said projecting electrode end exposing step.
